(19) United States
(12) Patent Application Publication
(10) Pub. No.: US 2006/0119410 A1
(43) Pub. Date: Jun. 8, 2006

(54) Pulse-rejecting circuit for suppressing single-event transients

(75) Inventor: Roy M. Carlson, Plymouth, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/005,265

(22) Filed: Dec. 6, 2004

(51) Int. Cl. H03K 5/08

(52) U.S. Cl. 327/310

(57) ABSTRACT

A circuit for rejecting single-event transients (SETs) from logic signals is provided. The circuit includes a delay circuit, an inverter circuit, and an output-holding circuit. The delay circuit receives an input signal and delays the input signal to produce a time-delayed version of the input signal. The input signal and the time-delayed version of the input signal are fed into the inverter circuit that propagates a corresponding output signal only when the input signal and the time-delayed version of the input signal have the same logic level. If the input signal or the time-delayed version of the input signal transitions such that both input signals presented to the inverter circuit have opposite logic levels, the output-holding circuit maintains the output signal in its previous state.

### GOVERNMENT RIGHTS

The United States Government has acquired certain rights in this invention pursuant to Contract No. DTRA01-02-D-0008 awarded by the Defense Threat Reduction Agency (DTRA).

### BACKGROUND

1. Field of the Invention

The present invention generally relates to particle-induced disturbances in microelectronic circuits and, more particularly, to suppressing transient pulses occurring within logic signals.

2. Description of Related Art

Integrated circuits used in space, weapons, or aviation applications must be more resistant to radiation than circuits used in other applications, because they are more likely to be exposed to radiation, and because their reliability is often more critical. Such solid-state circuits are vulnerable to disturbances caused by single, charged particles. Some examples of these particles are:
Alpha particles: These are the byproducts of the natural decay of elements such as uranium and thorium present in some integrated circuit packaging materials.
Energetic (having kinetic energy) protons, neutrons, electrons, heavy ions, and all the natural elements. These are abundant in intergalactic space, earth orbital space and even at high atmospheric altitudes (e.g., commercial flight altitudes) in a wide range of energies.

When a charged particle passes through a transistor (or any active electronic device), the particle loses energy by ionizing the medium through which it passes, leaving behind a track of hole-electron pairs. The electrons will migrate toward high voltage state nodes of the struck transistor, resulting in a discharging current on that node. If the discharging current exceeds the current drive of the transistor holding the high voltage state on that node, the node will transition to the undesired low state. The holes will migrate toward low voltage state nodes of the struck transistor resulting in a charging current on that node. If the charging current exceeds the current drive of the transistor holding the low voltage state on that node, the node will transition to the undesired high state. The number of hole-electron pairs created by the particle is finite, so the node voltage disturbance is temporary.

Particle-induced circuit disturbances are random and are commonly referred to as single-event effects (SEEs). The SEEs can take on many forms. If the particle strike results in a bit flip or other form of corruption of stored data, this is known as a single-event upset (SEU), or a soft error. If the particle causes a transient voltage disturbance on a node of a logic circuit, this is known as a single-event transient (SET).

A circuit node will typically return to the desired voltage state after a SET. Thus, a SET, in and of itself, may not be a problem. What is likely to be a problem is the consequence of having a temporary voltage disturbance on a circuit node. As an example, if the node is in a clock network, the SET can generate a false clock pulse in a portion of the system. If the node is in the logic that feeds data to an input of a latch (or other type of a memory element), there may or may not be a consequence from the SET. More particularly, if the data input recovers to the valid state from the SET before the latch closes, there is not likely to be a consequence. However, if the data input does not recover to the valid state from the SET before the latch closes, then the wrong data state is loaded into the latch. As a result, a SET-induced SEU occurs.

The susceptibility of modern integrated circuits to SETs is heightened by the reduced feature sizes of integrated circuits and higher clock speeds that are otherwise very desirable. As the feature sizes continue to decrease, SETs are more likely to propagate through logic gates as normal logic pulses, causing upsets within logic circuits. Thus, a solution that hardens logic circuits against SETs is needed.

### SUMMARY OF THE INVENTION

The present invention provides a pulse-rejecting circuit for hardening logic circuitry against SETs.

In one embodiment of the invention, the pulse-rejecting circuit includes (i) a delay circuit, (ii) an inverter circuit having a first input, a second input electrically coupled to the delay circuit, and an output, and (iii) an output-holding circuit coupled to the output of the inverter circuit. In operation, the delay circuit receives an input signal and delays the input signal by a predetermined time delay to produce a time-delayed version of the input signal. The input signal and the time-delayed version of the input signal are in turn provided to the inverter circuit that is configured to receive the input signal via the first input and the time-delayed version of the input signal via the second input.

The inverter circuit operates to propagate an output signal with a corresponding output value only when both the input signal and the time-delayed version of the input signal present on the respective inputs to the inverter circuit have the same logic level. In turn, during a period when the input signal and the time-delayed version of the input signal present opposite logic levels to the inverter circuit, the output-holding circuit holds the output signal at the corresponding output level. This way, if the predetermined time delay is selected to be longer than respective durations of transient pulses occurring on the input signal, the input signal and the time-delayed version of the input signal will not experience pulse-induced signal transitions simultaneously, and the transient pulses will be blocked from propagating onto the output signal.

According to the embodiment, the pulse-rejecting circuit can be connected in a signal path between a first logic block that provides the input signal and a second logic block that receives the output signal, such that transient pulses occurring on the input signal are blocked from appearing within the output signal provided to the second logic block. In one example, the first logic block could be combinational logic, whereas the second logic block could be a memory element, such as a random access memory (RAM), latch, flip-flop, or a register. Advantageously, SETs rejected from signals provided to the memory element will not cause SET-induced upsets within that element.

This as well as other aspects of the present invention will become apparent to those of ordinary skill in the art by reading the following detailed description, with appropriate reference to the accompanying drawings.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 is a block diagram of a circuit in which a disclosed embodiment of the invention may be employed.

FIG. 2A and FIG. 2B are timing diagrams of example signal transitions in the absence of transient disturbances.

FIG. 3 is a timing diagram of example signal transitions in the presence of transient disturbances;

FIG. 4 is a circuit diagram of a representative inverter circuit;

FIG. 5A is a circuit diagram of a conventional Complementary Metal Oxide Semiconductor (CMOS) inverter;

FIG. 5B is a circuit diagram of a stacked-gate inverter;

FIG. 6 is a circuit diagram of a representative output-holding circuit; and

FIG. 7 is a preferred embodiment of a delay circuit.

### DETAILED DESCRIPTION

1. Overview

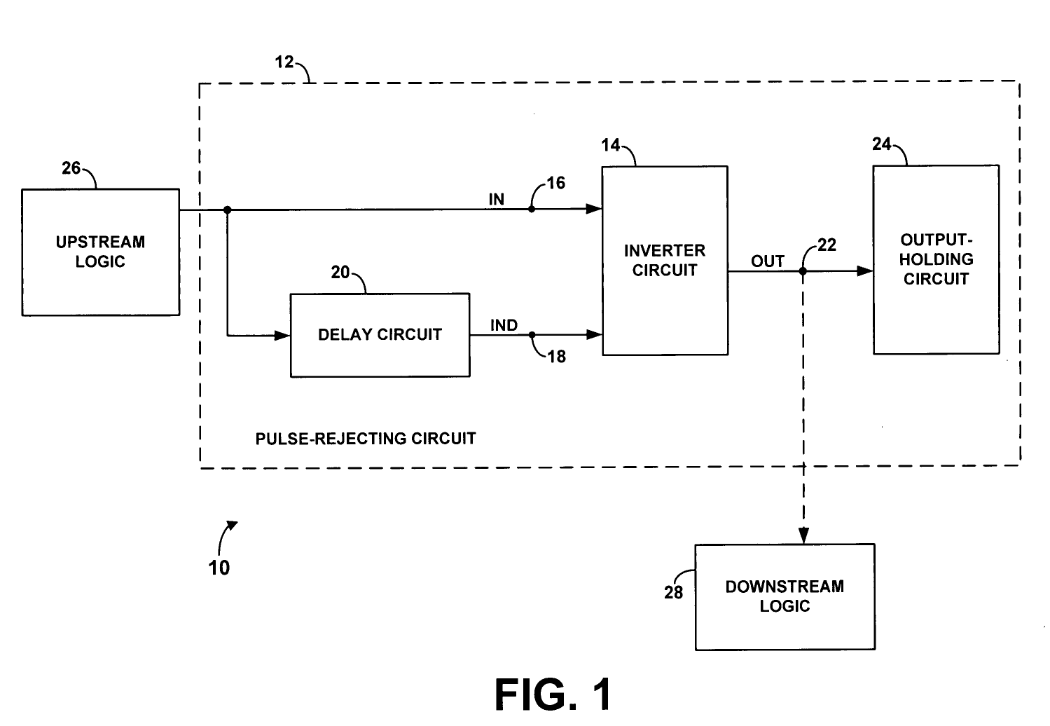

FIG. 1 illustrates a simplified block diagram of a logic circuit 10, which includes a pulse-rejecting circuit 12 in accordance with a disclosed embodiment of the present invention. As illustrated in FIG. 1, pulse-rejecting circuit 12 comprises an inverter circuit 14 that receives input signals via a direct input 16 and a delayed input 18, a delay circuit 20 coupled to delayed input 18, and an output-holding circuit 24 coupled to an output 22 of inverter circuit 14. Additionally, direct input 16 may be coupled to an upstream logic block 26, whereas output 22 may coupled to a downstream logic block 28.

In operation, an input signal IN and a time-delayed version of the IN signal are fed into inverter circuit 14 via respective direct input 16 and delayed input 18. More particularly, as shown in FIG. 1, the IN signal present on direct input 16 passes through delay circuit 20 and appears on delayed input 18 as a time-delayed input signal IND. For the purposes of the invention, delay circuit 20 is configured to produce the IND signal with substantially the same voltage level as the IN signal, but delayed in time with respect to the IN signal by a delay of T_{DINV}, where T_{DINV} represents a delay time.

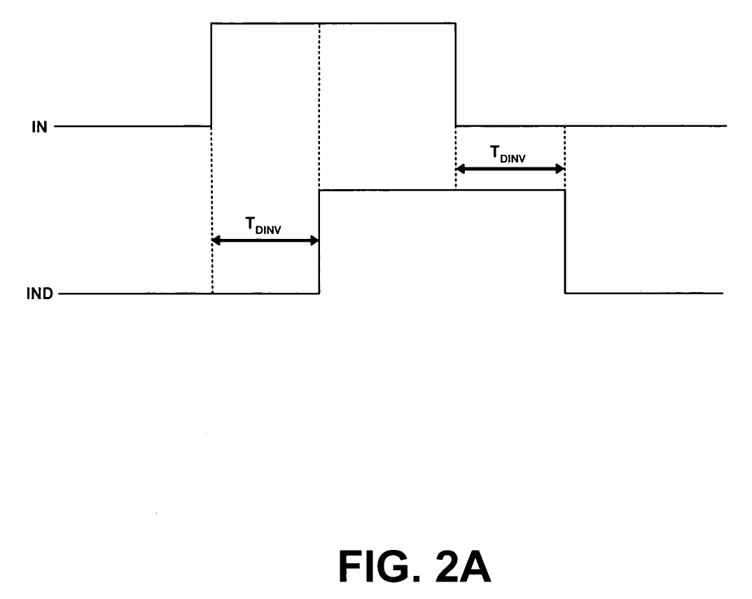

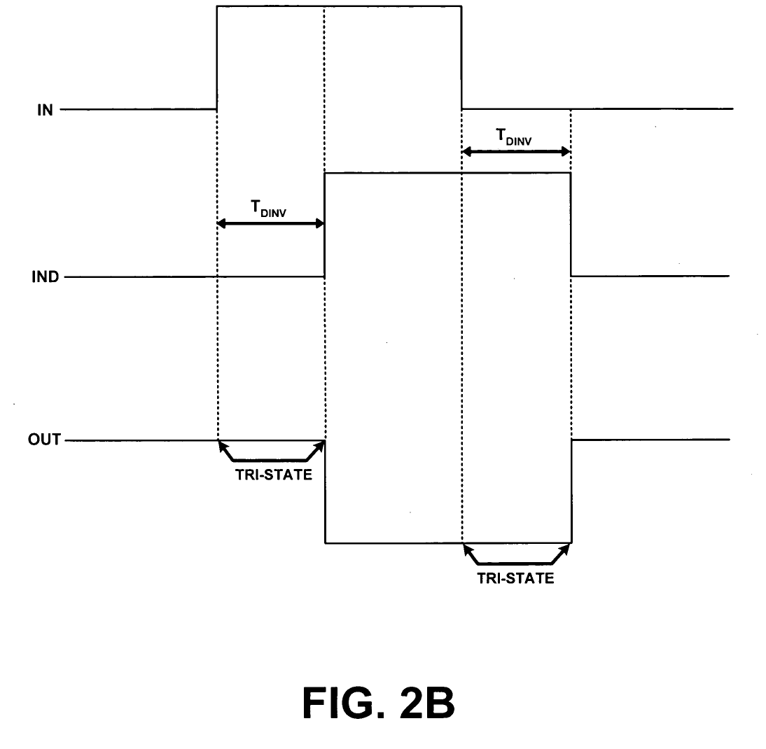

For instance, if the IN signal on direct input 16 undergoes a “low-to-high” logic transition (e.g., 0 V_{DC} to +5 V_{DC}), the IND signal on delayed input 18 undergoes the same “low-to-high” logic transition after the delay of T_{DINV}. Similarly, if the IN signal on the direct input undergoes a “high-to-low” logic transition (e.g., +5 V_{DC} to 0 V_{DC}), the IND signal on the time-delayed undergoes the same “high-to-low” logic transition after the delay of T_{DINV}. As an example, FIG. 2A illustrates a timing diagram of example logic level transition that may occur on the IN and IND signals in the absence of transient voltage disturbances.

According to the disclosed embodiment, inverter circuit 14 is configured to receive the direct input signal and the time-delayed input signal via respective inputs 16 and 18, and propagate a corresponding OUT signal onto output 22 only when the direct input signal and the time-delayed input signal have equivalent logic levels. Otherwise, the inverter circuit holds the OUT signal in its previous logic state. In effect, the inverter circuit 14 does not switch the logic state of the OUT signal at output 22 unless both the direct and time-delayed input signals present on its respective inputs have the same logic level. During normal operation, inverter circuit 14 performs logical inversion of input signals (i.e., “low” to “high” or “high” to “low”) and the corresponding OUT signal is an inverted version of the IN signal.

FIG. 2B depicts a timing diagram of example logic level transitions that may occur on the OUT signal in the absence of transient voltage disturbances. As shown in FIG. 2B, when the IN signal and IND signals are both “low”, the OUT signal is “high”. Following a “low-to-high” logic transition on the IN signal, the IN and IND signals are in opposite logical states until after the delay of T_{DINV}. Accordingly, the OUT signal remains in its previous logic state, i.e., “high”, for the duration of the delay. After the delay time T_{DINV}, the IND signal transitions from “low” to “high” and the IN and IND signals are both “high”. Since the IN and IND signals have the same logic level, the OUT signal switches from “high” to “low”.

Similarly, following a “high-to-low” logic transition on the IN signal, the IN and IND signals are in opposite logical states until after the delay of T_{DINV}. Accordingly, the OUT signal remains in its previous logic state, i.e., “low”, for the duration of the delay. After the delay time T_{DINV}, the IND signal transitions from “high” to “low” and the IN and IND signals are both “low”. Since the IN and IND signals have the same logic level, the OUT signal switches from “low” to “high”.

Additionally, as illustrated in FIG. 2B, during the periods when the IN and IND signals present opposite logic levels to inverter circuit 14, i.e., after the IN signal transitions to a new logic level but before the IND transitions to the same logic level, output 22 is in tri-state mode, or a high-impedance state that does not provide an output drive and that may be susceptible to noise. Rather than leaving the output of the inverter in the tri-state mode (or floating), output-holding circuit 24 is provided to maintain the output level of the OUT signal until the IN and IND signals transition accordingly to have the same logic level.

In practice, upstream logic block 26 may propagate a particle-induced SET onto the IN signal that feeds into inverter circuit 14. Upstream logic block 26 may include combinational (or non-memory) logic elements that are typically susceptible to disturbances caused by particle strikes, such as SETs. The propagated SET may appear in the IN signal in the form of a transient pulse (or signal glitch) that causes the IN signal to transition temporarily to an incorrect logic state. In a similar way, the replica of the SET within the IN signal may propagate through delay circuit 20 and appear in the IND signal, causing a temporary transition of the IND signal to the same incorrect logic state. As noted above, however, due to the delay effect of delay circuit 20, the transient pulse on the IND signal will lag behind the transient pulse on the IN signal with the delay of T_{DINV}.

If the time delay between the IN signal on direct input 16 and the IND signal on delay input 18 is selected to be longer than the duration of the transient pulse carried within the IN signal, the transient pulse will not appear at both of the inputs simultaneously. As a result, input signal transitions induced by the transient pulse will not trigger changes in the logic state of the OUT signal and the pulse will not propagate to output 22. In this manner, SETs having durations of less than a predetermined time delay provided by delay circuit 20 will be rejected by inverter circuit 14, while the correct logic state of the OUT signal on output 22 will be maintained by output-holding circuit 24 during tri-state periods.

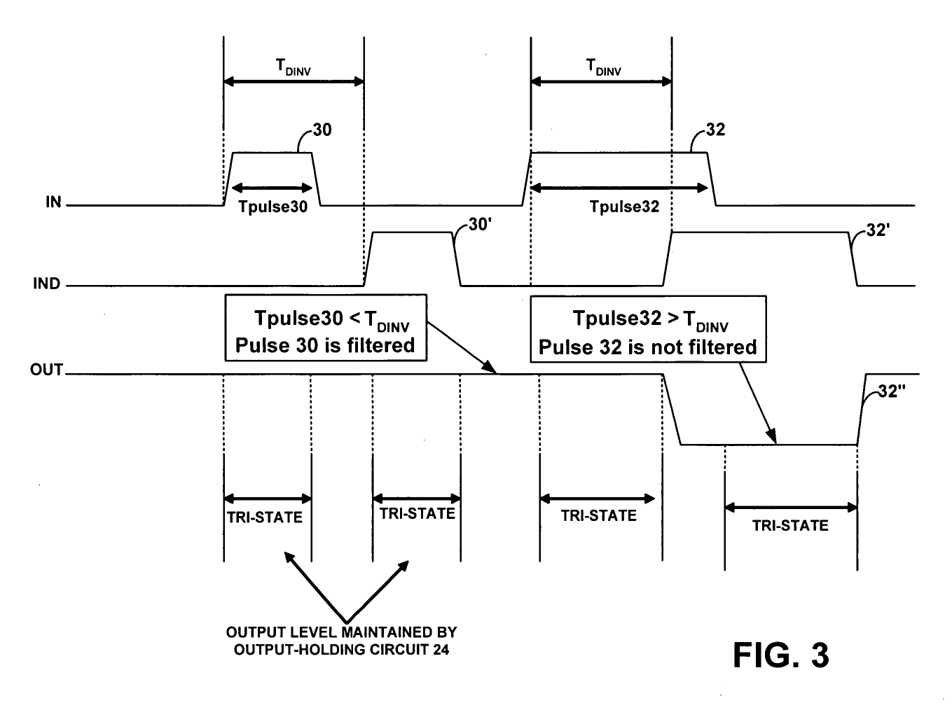

To illustrate this, FIG. 3 shows a timing diagram of signal transitions of the IN, IND, and OUT signals in the presence of two SET-induced voltage disturbances. FIG. 3 illustrates two scenarios, in which (i) the time delay between the IN signal and IND signal is longer than a duration of a first transient pulse and (ii) the time delay between the IN signal and IND signal is shorter than a duration of a second transient pulse.

Note that the transient pulses of FIG. 3 are shown as non-ideal rectangular pulses to illustrate finite rise and fall times that may be associated with the actual pulses appearing on the input signals. Additionally, tri-state periods are marked in FIG. 3.

As shown in FIG. 3, the IN and IND signals are initially “low” and the OUT signal is “high”. The IN signal then becomes disturbed by two “low-to-high-to-low” transient pulses 30 and 32, each having a duration of T_{PULSE30} and T_{PULSE32} respectively. In the first scenario, transient pulse 30 appears on the IN signal and, after the delay time T_{DINV}, a delayed transient pulse 30′ appears on IND signal. Since T_{DINV} is greater than T_{PULSE30}, transient pulse 30 and delayed transient pulse 30′ do not overlap in time. That is, by the time delayed transient pulse 30′ appears on the IND signal, transient pulse 30 on the IN signal has already passed. As a result, the IN and IND signals have opposite logic levels for the duration of the pulse-induce transition on the IN signal and for the duration of the pulse-induced transition on the IND signal. Accordingly, the OUT signal is maintained at logical “high” and transient pulse 30 does not propagate to output 22. Consequently, transient pulse 30 is filtered.

In the second scenario, transient pulse 32 that appears on the IN signal and a delayed transient pulse 32′ that appears on IND signal temporarily overlap in time, since T_{PULSE32} is greater than T_{DINV}. As a result, the IN and IND signals have the same logic level for the duration of the overlap between transient pulse 32 and delayed transient pulse 32′. This triggers the OUT signal to switch to the incorrect “low” state.

As further shown in FIG. 3, after the temporary overlap between transient pulse 32 and delayed transient 32′ ends, the IN and IND signals have again opposite logic levels, since delayed transient pulse 32′ on the IND signal has yet to fully pass. This, in turn, prevents the OUT signal from switching back to its previous “high” state. The OUT remains in the “low” state until delayed transient pulse 32′ on the IND signal fully passes. When the IND signal switches back from “high” to “low”, the “OUT” signal switches from “low” to “high” and a transient pulse 32″ is propagated onto the OUT signal.

To prevent this second scenario, in the disclosed embodiment, a predetermined time delay between the direct input signal and the time-delayed input signal to inverter circuit 14 is designed to be longer than a maximum duration of a SET pulse carried within the direct input signal. In this manner, pulse-rejecting circuit 12 will preferably block SET pulses from propagating onto the OUT signal.

2. Inverter Circuit

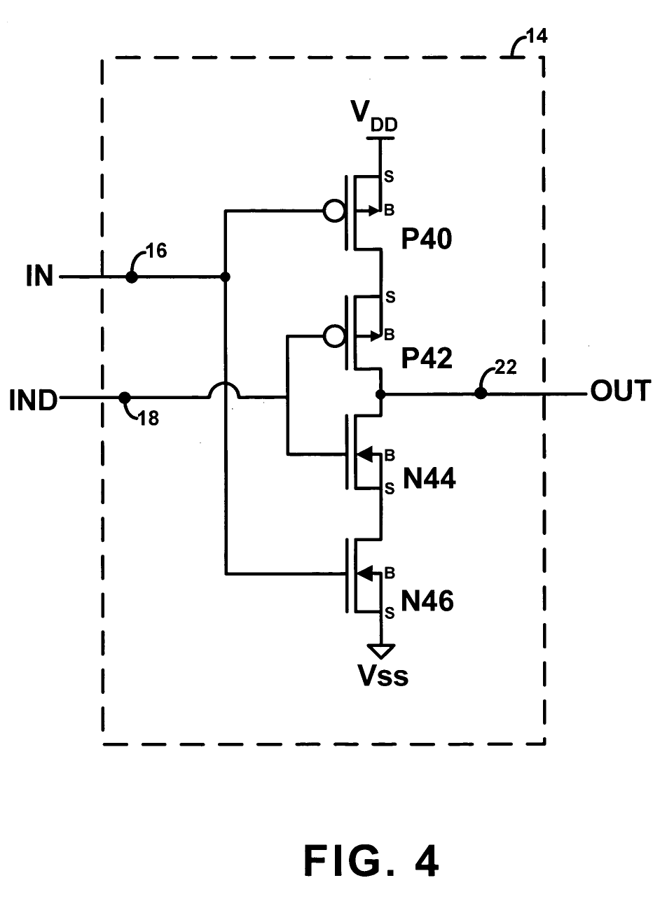

FIG. 4 depicts a circuit diagram of representative inverter circuit 14. As depicted in FIG. 4, inverter circuit 14 may be implemented with N-channel and P-channel Metal Oxide Semiconductor (MOS) transistors that conventionally have a gate, a source, a drain, and body (or substrate) terminals. The technology that utilizes both P- and N-channel devices is known in the art as the Complementary Metal Oxide Semiconductor (CMOS) technology.

In practice, a MOS transistor is controlled (i.e., turned “on” or “off”) by a voltage that is applied at a gate of the transistor. In particular, when a voltage of sufficient magnitude (typically greater than a given threshold voltage for an N-channel MOS transistor and less than a given threshold voltage for a P-channel MOS transistor) is applied to the gate of the transistor in an “off” state, a conductive channel is induced within the transistor such that a current flows between a drain and a source, turning the transistor “on”. By connecting N-channel and P-channel transistors in a complementary fashion, an inverting logic function can be realized.

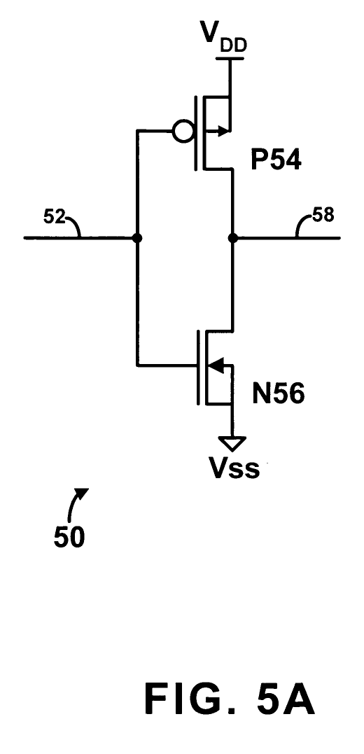

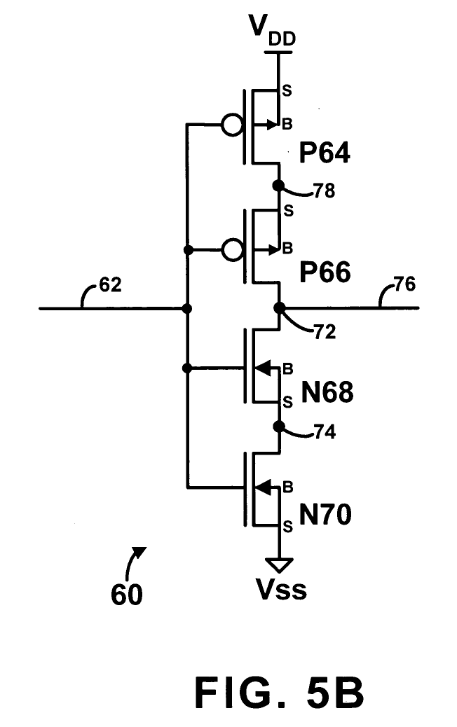

As an example, FIG. 5A illustrates a circuit diagram of a conventional CMOS inverter 50. As known to those skilled in the art, the conventional CMOS inverter of FIG. 5A operates to assert an output logic signal that is a logic complement of the input signal to the inverter. In a typical inverter operation, if an input signal 52 is “low” (e.g., corresponding to a logical “0”), a P-channel transistor 54 is turned on, an N-channel transistor 56 is turned “off”, and an output signal 58 is pulled up to a positive supply voltage V_{DD} and is thus “high” (e.g., corresponding to a logical “1”). Similarly, if input signal 52 is “high” (e.g., corresponding to a logical “1”), P-channel transistor 54 is turned “off”, N-channel transistor 56 is turned “on”, and output signal 58 is pulled down to a ground potential V_{SS} and is thus “low”.

One of the shortcomings of the conventional CMOS inverter illustrated in FIG. 5A is that it does not provide any hardening against single-event disturbances such as SETs. As an example, consider a scenario in which a particle strike occurs on N-channel transistor 56 when P-channel transistor 54 is “on” and N-channel transistor 56 is “off”. The particle strike may disturb the output voltage state of output signal 58 because the created charge in the N-channel transistor may result in a pull-down current within the N-channel transistor to the ground potential V_{SS} competing against a pull-up current within the P-channel transistor to the positive supply voltage V_{DD}. If the pull-down current is sufficiently larger than the pull-up current that holds the voltage state of the output signal at “high”, the output voltage will temporarily transition to the undesired “low” state. If the particle-induced output voltage state falls past the switch point of a following logic gate, then a SET is propagated to a downstream logic.

The representative inverter circuit of FIG. 4 is a modified version of a SET-hardened stacked-gate inverter 60 illustrated in FIG. 5B and also described in detail in the U.S. Provisional Patent Application No. 60/384,585, filed on May 31, 2002, entitled “SET/SEU Hardened Stacked-Gate Circuits”, to Keith W. Golke, the entirety of which is hereby incorporated by reference. In summary, the stacked-gate inverter configuration of FIG. 5B can be realized by replacing single P-channel and N-channel transistors of conventional CMOS inverter 50 shown in FIG. 5A with a respective P-channel and N-channel MOS transistor stack comprising a pair of series-connected transistors. The substrate, or body, terminal of each of the replacing MOS transistors is preferably connected to the source terminal as shown in FIG. 5B.

Stacked-gate inverter 60 of FIG. 5B provides operational advantages over the conventional CMOS inverter of FIG. 5A, because it is hardened against creation of SETs from single particle strikes. In particular, the stacked-transistor inverter structure illustrated in FIG. 5B ensures that there are always at least two “off” transistors between any critical circuit node (i.e., a node that, when disturbed, can cause an upset, e.g., an output node), and V_{DD}/V_{SS}, and between critical nodes. Thus, when/if a particle strikes one of the “off” stacked transistors, the other “off” transistor prevents the resulting current from reaching the critical node or from reaching V_{DD}/V_{SS}, and no SET occurs.

Although the circuit configuration of FIG. 5B includes a body-to-source connection on each of the stacked transistors to increase SET-hardening benefits of the stacked-gate inverter, other circuit configurations are possible as well and are described in greater detail in the Golke provisional application. In operation, if an input signal 62 is “low”, then P-channel transistor 64 and P-channel transistor 66 are “on”, N-channel transistor 68 and N-channel transistor 70 are “off”, and an output signal 76 is “high”. A particle strike on N-channel transistor 68 will create a drain-to-body and a drain-to-source pull-down current in N-channel transistor 68. Since the body terminal of N-channel transistor 68 is connected to the source terminal of N-channel transistor 68, both of these currents are directed from an output node 72 to a node 74. With N-channel transistor 70 being off, the current path is cut off from the ground. Thus, the only current that flows is the displacement current that results from charging the capacitance on node 74 from output node 72. Generally, this capacitance is much smaller than the capacitance on output node 72 so this has little effect on output signal 76.

In turn, a particle strike on N-channel transistor 70 will create a drain-to-body and a drain-to-source pull-down current in N-channel transistor 70. Since the body terminal of N-channel transistor 70 is connected to the source terminal N-channel transistor 70, both of these currents are directed from node 74 to the ground potential V_{SS}. With N-channel transistor 68 being off, the current path is cut off from output node 72 and there is no current flow to output node 72.

Similarly, if input signal 62 is “high” then P-channel transistor 64 and P-channel transistor 66 are “off”, N-channel transistor 68 and N-channel transistor 70 are “on” and output signal 76 is “low”. A particle strike on P-channel transistor 66 will create a drain-to-body and a drain-to-source pull-up current in P-channel transistor 66. Since the body terminal is connected to the source terminal of P-channel transistor 66, both of these currents are directed from output node 72 to a node 78. With P-channel transistor 64 being “off”, the current path is cut off from the positive supply voltage V_{DD}. Thus, the only current that flows is the displacement current that results from charging the capacitance on node 78 from output node 72. Generally, this capacitance is much smaller than the capacitance on output node 72 so this has little effect on output signal 76. In turn, a particle strike on P-channel transistor 64 will create a drain-to-body and a drain-to-source pull-up current in P-channel transistor 64. Since the body terminal of P-channel transistor 64 is connected to the source terminal of P-channel transistor 64, both of these currents are directed from node 78 to the positive supply voltage V_{DD}. With P-channel transistor 66 being “off”, the current path is cut off from output node 72 and there is no current flow to output node 72.

Although stacked-gate inverter 60, as described above, is hardened against formation of SETs within the inverter itself, its single-input circuit structure generally does not provide hardening against SETs that may be generated by other logic elements and that may propagate onto the input signal to the stacked-gate inverter. As such, if a SET appears at the input to the stacked-gate inverter, the stacked-gate inverter will typically propagate the SET (or, more particularly, an inverted version of the SET) onto its output as it would any other legitimate logic pulse.

As an example, a presence of “low-to-high-to-low” SET on “low” input signal 72 may cause N-channel transistor 68 and N-channel transistor 70 to be simultaneously switched “on” for the duration of the SET, thus causing a logic state change on output signal 76 from “high” to “low”. When the input signal falls back “low” at the end of the SET-induced input transition, the inverted version of the SET is fully propagated onto the output signal.

In the disclosed embodiment, the stacked-gate inverter has been modified to provide a dual-input inverter structure that provides the SET-hardening benefits of the single-input structure, but additionally allows for switching the inputs in a staggered fashion rather than simultaneously.

More particularly, as shown in FIG. 4, the gates of a P-channel transistor 40 coupled to the positive supply voltage V_{DD} and a N-channel transistor 46 coupled to the ground potential V_{SS} are connected together to form direct input 16, while the gates of a P-channel transistor 42 and a N-channel transistor 44 are connected together to form delayed input 18. The body terminal of each of the stacked transistors is preferably connected to the source terminal to increase SET-hardening effects of the inverter circuit.

The inverter circuit of FIG. 4 operates in the following matter. When the IN and IND signals are both “low”, P-channel transistors 40 and 42 are “on”, N-channel transistors 44 and 46 are “off”, and the OUT signal is “high”. In contrast, when the IN and IND signals are both “high”, P-channel transistors 40 and 42 are “off”, N-channel transistors 44 and 46 are “on”, and the OUT signal is “low”. Thus, in response to and IN and IND signals being in the same logic state, the inverter circuit propagates the corresponding OUT signal onto output 22.

Now suppose a transient glitch occurs on the IN signal, causing the IN signal at direct input 16 to transition to an opposite logic state, e.g., from “low” to “high”. In accordance with the disclosed embodiment, the time delay between the IN signal and IND signal is designed to be longer than a duration of the transient glitch, such that the glitch does not appear at both of the inputs to inverter circuit 14 simultaneously. Thus the IN signal at direct input 16 remains “high” and the IND signal at delayed input 18 remains “low” for the duration of the glitch. The glitch-induced transition on the IN signal causes P-channel transistor 40 to be turned “off” and N-channel transistor 46 to be turned “on” until the glitch passes on the IN signal. Since N-channel transistor 44 remains “off” for the duration of the glitch-induced transition on the IN signal, the current path between output 22 and the ground potential V_{SS} is broken, and output 22 is isolated from the V_{SS}. Although P-channel transistor 40 also remains “off” during this period, the charged capacitance on output 22 will temporarily hold the OUT signal in its previous “high” state.

After the delay time elapses, the delayed version of the transient glitch will appear on the IND signal, causing the IND signal at delayed input 18 to transition to an opposite logic state, i.e., from “low” to “high”, while the IN has returned back to the “low” state. The glitch-induced transition on the IND signal will cause P-channel transistor 42 to be turned “off” and N-channel transistor 44 to be turned “on” until the glitch passes on the IND signal. Since N-channel transistor 46 remains “off” for the duration of the glitch-induced transition on the IN signal, the current path between output 22 and the ground potential V_{SS} is broken, and output 22 is isolated from the V_{SS}. Although P-channel transistor 42 also remains “off” during this period, the charged capacitance on output 22 will temporarily hold the OUT signal in its previous “high” state.

Similarly, a transient glitch may occur on the IN signal that causes the IN signal at direct input 16 to transition from “high” to “low”. Again, in accordance with the disclosed embodiment, the time delay between the IN signal and IND signal is designed to be longer than a duration of the transient glitch, such that the glitch does not appear at both of the inputs to inverter circuit 14 simultaneously. Thus the IN at direct input 16 signal remains “low” and the IND signal at delayed input 18 remains “high” for the duration of the glitch. The glitch-induced transition on the IN signal causes P-channel transistor 40 to be turned “on” and N-channel transistor 46 to be turned “off” until the glitch passes on the IN signal. Since P-channel transistor 42 remains “off” for the duration of the glitch-induced transition on the IN signal, the current path between output 22 and the positive supply voltage V_{DD} is broken, and output 22 is isolated from the V_{DD}. Although N-channel transistor 46 also remains “off” during this period, the charged capacitance on output 22 will temporarily hold the OUT signal in its previous “low” state.

After the delay time elapses, the delayed version of the transient glitch will appear on the IND signal, causing the IND signal at delayed input 18 to transition to an opposite logic state, i.e., from “high” to “low”, while the IN has returned back to the “low” state. The glitch-induced transition on the IND signal will cause P-channel transistor 42 to be turned “on” and N-channel transistor 44 to be turned “off” until the glitch passes on the IND signal. Since P-channel transistor 40 remains “off” for the duration of the glitch-induced transition on the IN signal, the current path between output 22 and the positive supply voltage V_{DD} is broken, and output 22 is isolated from the V_{DD}. Although N-channel transistor 44 also remains “off” during this period, the charged capacitance on output 22 will temporarily hold the OUT signal in its previous “low” state.

Additionally, as described above, the stacked-transistor architecture of representative inverter circuit 14, including the preferred body-to-source connections on each stacked transistor as shown in FIG. 4, is generally hardened against single particle strikes on individual “off” transistors, so that inverter circuit 14 itself does not cause undesirable transitions on the OUT signal. In one scenario, however, when a particle strike occurs on P-channel transistor 42 or N-channel transistor 44 after the IN signal switches to a new value but before the IND switches to the same value, the particle strike could cause the OUT signal to transition early. However, this premature transition on the OUT signal would still be in the direction of the final correct transition.

As an example, if the IN and IND signals are “low”, P-channel transistors 40 and 42 are “on”, N-channel transistors 44 and 46 are “off”, and the OUT signal is “high”. After the IN signal transitions to “high” but before the IND signal undergoes the same “low-to-high” transition, P-channel transistor 40 is “off”, P-channel transistor 42 is “on”, N-channel transistor 44 is “off”, N-channel transistor 46 is “on”, and the OUT signal remains “high”. If a particle strikes N-channel transistor 44, this may cause a current to flow through N-channel transistor 44, essentially creating a current path from output 22 to the ground potential V_{SS} and thus pulling the OUT signal “low”. When the IND signal switches “high”, this would normally turn P-channel transistor 42 and N-channel transistor 44 back “on”, pulling the OUT signal from the tri-state mode and into the final “low” logic transition. However, since the “OUT” signal has already transitioned to the “low” state, the value of the OUT signal remains unchanged. In effect, the result of the particle strike to N-channel transistor 44 is a premature transition on the “OUT” signal into its final correct logic state.

Further, as noted above, during tri-state periods when the IN and IND signals present opposite logic levels to inverter circuit 14, for example, during periods when the IN and IND signals remain in opposite logic states because one of them experiences a SET-induced signal transition, the capacitance on output 22 will temporarily keep the OUT signal in its previous state, i.e., the state of the OUT signal prior to the occurrence of the SET-induced input signal transition. The output capacitance of inverter circuit 14 may be a parasitic capacitance of the inverter circuit itself and will typically depend on the particular circuit design and fabrication of the circuit elements, and/or may be provided by the input of following logic gate(s).

Although the output capacitance may keep the tri-stated value of the OUT signal relatively constant for some time, it will not typically be sufficient to prevent changes in value of the OUT signal for substantially long periods of time. In one example, if the time delay between the IN and IND signals is selected to be excessively long (e.g., to ensure that the time delay has enough margin to last longer than any transient pulse that may disturb the IN signal), the output capacitance will likely not be able to sustain the value of the OUT signal during the entire period between when the IN signal transitions to a new logic state but before the IND signal transitions to the same logic state.

Further, although SETs have typically very short time durations (e.g, 100-200 ps), some may last up to several nanoseconds and it may be possible that the output capacitance of inverter circuit 14 will not have enough charge to hold the level of the OUT signal constant for the entire duration of a given SET. Yet further, the output capacitance of inverter circuit 14 will generally not provide much signal immunity against other types of circuit disturbances, such as noise for instance.

3. Output-Holding Circuit

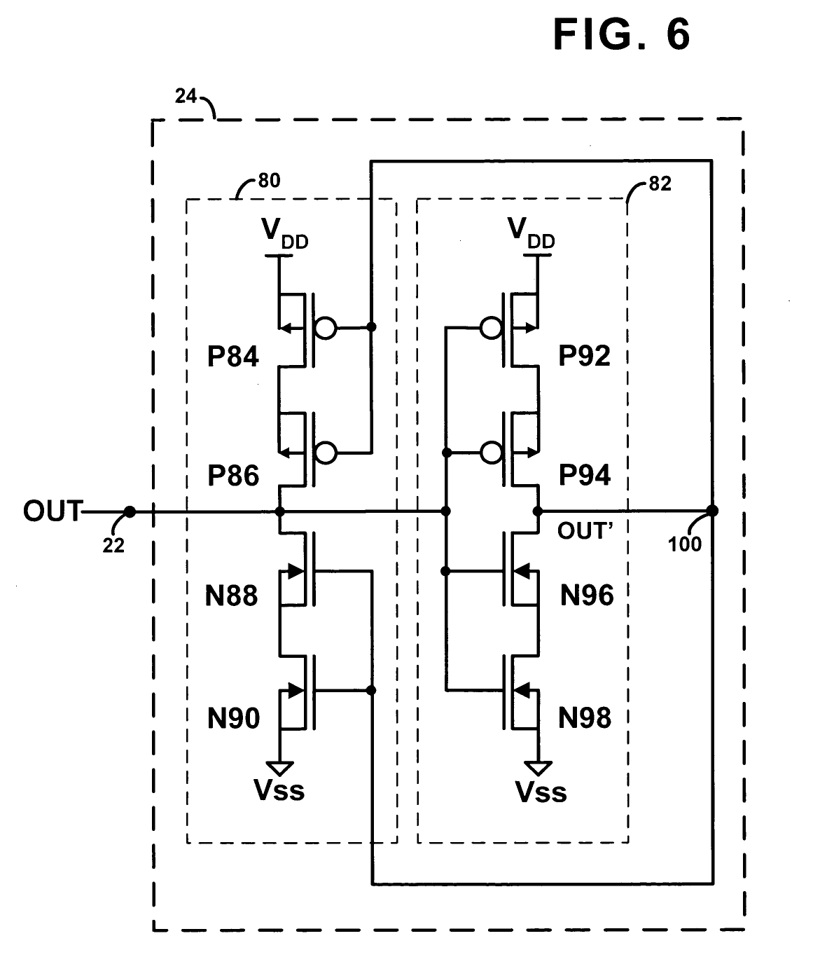

In accordance with one embodiment of the invention, output-holding circuit 24 is added on the output of inverter circuit 14 to maintain the value of the OUT signal during tri-state periods when the IN and IND signals present opposite logic levels to inverter circuit 14. FIG. 6 illustrates in greater detail representative output-holding circuit 24.

The representative output-holding circuit is configured using two electrically coupled stacked-transistor inverter structures 80 and 82 that function to hold output 22 at (i) the ground potential V_{SS} when the OUT signal is “low” and (ii) the positive supply voltage V_{DD} when the OUT signal is “high”. As shown in FIG. 6, the gates of respective transistors of stacked-transistor inverter structure 82 are connected to output 22, such that stacked-transistor inverter structure 82 produces an inverted version of the OUT signal (OUT′) at an output node 100. Output node 100 is, in turn, connected to the gates of respective transistors of stacked-transistor inverter structure 80 whose output terminal is electrically tied to output 22.

In operation, when the OUT signal at output 22 is “high”, P-channel transistors 92 and 94 are “off” and N-channel transistors 96 and 98 are “on”, and the OUT′ is “low”. In turn, the “low” OUT′ signal turns P-channel transistors 84 and 86 “on” and N-channel transistors 88 and 90 “off”, such that output 22 is pulled up to the positive supply voltage V_{DD}.

Similarly, when the OUT signal at output 22 is “low”, P-channel transistors 92 and 94 are “on” and N-channel transistors 96 and 98 are “off”, and the OUT′ is “high”. In turn, the “high” OUT′ signal turns P-channel transistors 84 and 86 “off” and N-channel transistors 88 and 90 “on”, such that output 22 is pulled down to the ground potential V_{SS}.

It should be noted that, in practice, P-channel transistors 40 and 42 of inverter structure 14 are preferably selected to be stronger (i.e., to have a stronger current drive) than N-channel transistors 88 and 90. This will ensure that when the OUT signal is switched from “low” to “high”, P-channel transistors 40 and 42 are strong enough to pull the OUT signal out of the “low” state. In the same way, N-channel transistors 44 and 46 of inverter structure 14 are preferably selected to be stronger than P-channel transistors 84 and 86 to ensure that when the OUT signal is switched from “high” to “low”, N-channel transistors 44 and 46 are strong enough to pull the OUT signal out of the “high” state.

The representative circuit structure of output-holding circuit 24 is substantially hardened against creation of SETs, since the stacked-transistor inverter structures 80 and 82, as described above, are hardened against upsets that may be caused by single particle strikes. This has the added benefit of reducing undesirable transitions on the OUT signal in the event that the output holding circuit itself is struck as a result of radiation, for instance. Additionally, by holding the OUT signal at a constant voltage, output-holding circuit 24 makes the OUT signal more robust against other types of circuit disturbances, such as noise, for instance.

4. Delay Circuit

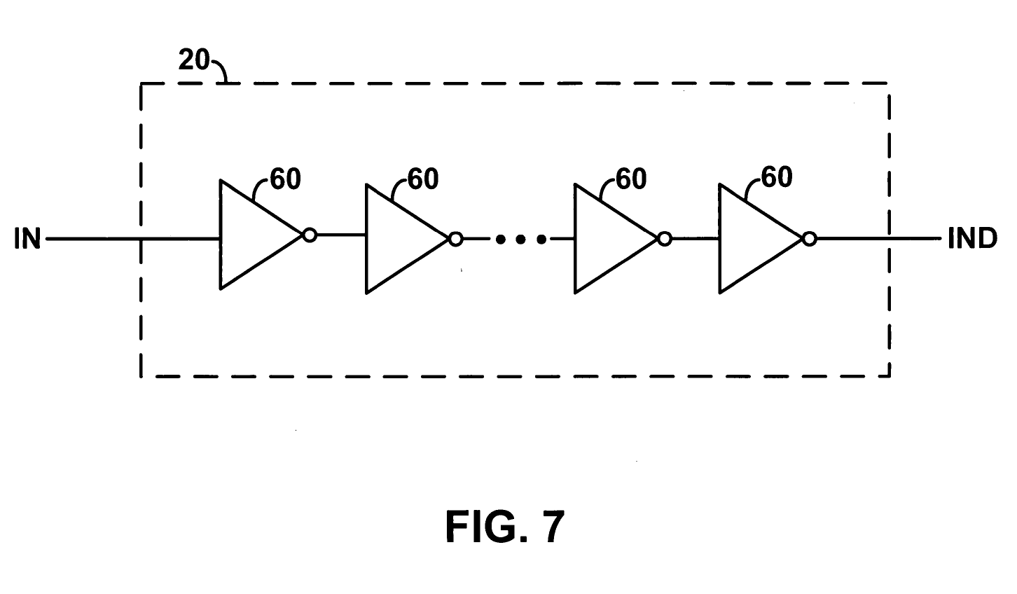

Now referring to FIG. 7, a preferred embodiment of delay circuit 20 will be described. In general, delay elements in logic circuits may be implemented using a number of logic inverter gates connected in a series configuration. A typical logic inverter gate has a finite delay, or propagation delay, such that a signal passing through the inverter gate is delayed for a time by the delay of the gate. If multiple logic inverter gates are connected in series to create a delay chain, the total propagation delay of the chain will be substantially equal to the sum of the propagation delays of each individual inverter gate within the chain. In addition, if an even number of inverter gates is used to construct the delay chain, the delay chain will realize a noninverting logic function.

Accordingly, delay circuit 20 can be constructed using a plurality of delay inverters connected in a non-inverting series configuration to produce a time-delayed version of an input signal provided to the delay circuit. As noted above, the non-inverting configuration can be realized with an even number of inverter gates. Further, in the preferred embodiment shown in FIG. 7, delay circuit 20 is additionally hardened against disturbances caused by single particle strikes by using stacked-gate inverter 60 as each of the delay inverters. The detailed discussion on the hardness of stacked-gate inverter has been presented above.

It should be noted that minimizing the susceptibility of the delay circuit to particle-induced upsets, as presently contemplated, is desirable in order to increase radiation hardness of pulse-rejecting circuit 12. In one example scenario, if the delay inverters are not hardened, the delay circuit itself may create transient pulses that can disturb the IND signal and can affect the logic state of the OUT signal. In another example scenario, the unhardened delay inverters can be disturbed by a particle strike in such a way that the IND signal essentially gets “stuck” at the same logic value as the IN signal. As a result, the next logic transition of the IN signal would be blocked by inverter circuit 14 until the strike subsides and the IND returns to the correct logic state. In yet another example scenario, the unhardened delay inverters can be disturbed by a particle strike in such a way that the IND transitions to a logic level that is opposite that of the IN signal. In effect, upon the next transition on the IND signal, the IN and IND signals would present the same logic level to inverter circuit 14 and the inverter circuit 14 would immediately propagate a corresponding value of the OUT signal onto output 22, essentially bypassing the delay circuit.

Advantageously, with the use of the preferred configuration for implementing delay circuit 20, such scenarios may be prevented. Additionally, the use of stacked-gate inverters 60 as the delay inverters of delay circuit 20 has the added benefit of slowing down the delay circuit. This can sometimes be difficult to accomplish on a low fan-out circuit. In effect, a desired amount of delay may be achieved with fewer inverter gates, yet further minimizing the susceptibility of the delay circuit to particle-induced disturbances.

6. Applications

According to the disclosed embodiment, pulse-rejecting circuit 12 may be connected in a signal path between upstream logic 26 and downstream logic 28 as shown in FIG. 1. As such, the pulse-rejecting circuit may function as a signal filter that provides a SET-filtered drive signal to downstream logic 28. In effect, downstream logic 28 may be hardened against SETs propagated onto the IN signal by the elements of upstream logic 26.

In one example, upstream logic 26 and downstream logic 28 may both represent combinational logic blocks. As noted above, combinational logic elements are typically susceptible to particle-induced disturbances, such as SETs. By connecting pulse-rejecting circuit 12 in a signal path between two combinational logic blocks, SETs propagated onto the output of one combinational logic block may be blocked from propagating down to the input of another combinational logic block.

In another example, downstream logic 28 could be a memory (or data storage) element, such as a random access memory (RAM), flip-flop, latch, register, or the like, and upstream logic 26 could be combinational logic that provides data to the memory element. Typically, if a SET is present at a data input pin of a memory element during critical clock transitions (e.g., on a falling or rising clock edge that triggers the storage element to load data present at its input(s)), the memory element may experience a SET-induced upset due to incorrect data being loaded into the element.

To prevent data storage errors due to SETs present on data signals supplied to memory elements, the pulse-rejecting circuit may be connected on data input line(s) feeding into the memory element(s) in order to filter SETs from the data signals. As an example, the pulse-rejecting circuit can be connected in an input data path to a register that holds critical data, such as program instructions for a computer processor used in space or aviation applications, in order to prevent SET-induced random data corruptions that normally could “confuse” the processor or even cause the processor to crash.

In a similar way, the pulse-rejecting circuit may be used to filter SETs present on clock signals or reset signals that are supplied as control signals to various logic circuits. For example, the occurrence of a SET on a clock signal may induce a clock transition that may trigger a data storage element to load the data present at its data input(s). As a result, the storage element may experience SET-induced upset due to incorrect data being stored in the element. In a similar way, if a SET occurs on a reset signal then the SET may cause all circuits connected to that signal to be reset. Of course, such random circuit resets would be highly undesirable in any critical application.

Again, by connecting the pulse-rejecting circuit on clock line(s) or reset line(s) feeding into downstream logic circuits(s), SETs may be filtered from those lines such that they do not cause circuit upsets. Those skilled in the art will recognize that if the pulse-rejecting circuit is connected on a clock or a reset line, the timing of those signals may be adjusted accordingly to account for the time delay of the pulse-rejecting circuit.

Further, although the pulse-rejecting circuit may be constructed from discrete logic gates, the pulse-rejecting circuit may also be conveniently fabricated using CMOS technology on a single Integrated Circuit (IC) chip that can be easily connected within logic circuitry.

7. Conclusion

While particular embodiments have been described, persons of skill in the art will appreciate that variations may be made without departure from the scope and spirit of the invention. This true scope and spirit is defined by the appended claims, which may be interpreted in light of the foregoing.

I claim:

1. A circuit for hardening against single-event transients, the circuit comprising in combination:
a delay circuit, wherein the delay circuit receives an input signal and delays the input signal by a predetermined time delay to produce a time-delayed version of the input signal;
an inverter circuit electrically coupled to the delay circuit, wherein the inverter circuit is configured to receive the input signal and the time-delayed version of the input signal, and to propagate an output signal with a corresponding output logic level only when the input signal and the time-delayed version of the input signal have equivalent input logic levels; and
an output-holding circuit electrically coupled to the inverter circuit, wherein the output-holding circuit operates to hold the output signal at the corresponding output logic level when the input signal and the time-delayed version of the input signal have opposite input logic levels.

2. The circuit of claim 1, wherein the predetermined time delay is longer than respective durations of transient pulses occurring on the input signal.

3. The circuit of claim 2 adapted for connection in a signal path between a first logic block that provides the input signal and a second logic block that receives the output signal, such that the transient pulses occurring on the input signal provided by the first logic block are blocked from appearing within the output signal received by the second logic block.

4. The circuit of claim 3, wherein the first logic block includes combinational logic and the second logic block includes a memory element.

5. The circuit of claim 4, wherein the memory element is selected from the group consisting of (i) a random access memory (RAM), (ii) a latch, (iii) a flip-flop, and (iv) a register.

6. The circuit of claim 3, wherein the first logic block is a first combinational logic block and the second logic block is a second combinational logic block.

7. The circuit of claim 3, wherein the output signal is carried upon an input line connected to a plurality of logic elements.

8. The circuit of claim 3, wherein the output signal is selected from the group consisting of (i) a data signal, (ii) a clock signal, and (iii) a reset signal.

9. The circuit of claim 1, wherein the delay circuit, the inverter circuit and the output-holding circuit are each hardened against disturbances caused by single particle strikes.

10. The circuit of claim 9, wherein the delay circuit includes a plurality of logic inverter gates connected in a non-inverting series configuration, each series-connected logic inverter gate being individually hardened against the disturbances caused by single particle strikes.

11. The circuit of claim 10, wherein each series-connected logic inverter gate has a stacked-transistor inverter structure, the stacked-transistor inverter structure including:
a first transistor stack comprising a first P-channel Metal Oxide Semiconductor (MOS) transistor connected in series to a second P-channel MOS transistor, wherein the first P-channel transistor is electrically coupled to a high reference voltage and the second P-channel transistor is electrically coupled to an output node; and
a second transistor stack comprising a first N-channel MOS transistor connected in series to a second N-channel MOS transistor, wherein the first N-channel MOS transistor is electrically coupled to the output node and the second N-channel transistor is electrically coupled to a low reference voltage, and wherein gates of respective MOS transistors in the first transistor stack and the second transistor stack are connected together to an input node.

12. The circuit of claim 11, wherein the output-holding circuit is configured using a first stacked-transistor inverter structure and a second stacked-transistor inverter structure.

13. The circuit of claim 1, wherein the output-holding circuit functions to provide noise immunity to the output signal during a period when the input signal and the time-delayed version of the input signal have opposite logic levels.

14. The circuit of the claim 1, wherein during a period when the input signal and the time-delayed version of the input signal have equivalent logic levels, the output signal is an inverted version of the input signal.

15. The circuit of claim 1, wherein during a period when the input signal and the time-delayed version of the input signal have opposite logic levels, the output-holding circuit is designed (i) to hold the output signal at a low reference voltage if the corresponding output logic level is low and (ii) to hold the output signal at a high reference voltage if the corresponding output logic level is high.

16. A pulse-rejecting circuit for suppressing single-event transients in logic signals, the pulse-rejecting circuit comprising:
a delay circuit, wherein the delay circuit receives an input signal and produces a time-delayed version of the input signal, the time-delayed version being delayed in time with respect to the input signal by a predetermined time delay that is selected to be longer than a maximum duration of a transient pulse carried within the input signal;
an inverter circuit having a first input, a second input electrically coupled to the delay circuit, and an output, wherein the inverter circuit is configured to receive the input signal via the first input and the time-delayed version of the input signal via the second input, and wherein the inverter circuit operates to propagate an output signal with a corresponding output logic level onto the output only when the input signal on the first input and the time-delayed version of the input signal on the second input have equivalent input logic levels; and
an output-holding circuit electrically coupled to the output of the inverter circuit, the output-holding circuit being operative to hold the output signal at the corresponding output level when the input signal at the first input or the delayed version of the input signal at the second input experiences a pulse-induced signal transition that causes the input signal and the delayed version of the input signal to have opposite input logic levels.

17. The pulse-rejecting circuit of claim 16, wherein the transient pulse present at the first input to the inverter circuit appears at the second input to the inverter circuit after the predetermined time delay.

18. The pulse-rejecting circuit of claim 16 adapted for connection in a signal path between a first logic block that provides the input signal and a second logic block that receives the output signal, such that the transient pulse carried within the input signal is suppressed in the output signal received by the second logic block.

19. The circuit of claim 18, wherein the first logic block includes combinational logic and the second logic block includes a memory element.

20. The circuit of claim 16, wherein the first logic block is a first combinational logic block and the second logic block is a second combinational logic block.

21. The circuit of claim 1, wherein the delay circuit, the inverter circuit and the output-holding circuit are each hardened against disturbances caused by single particle strikes.

22. The circuit of claim 16 fabricated on a single Complementary Metal Oxide Semiconductor (CMOS) chip.
